(19) United States
(12) Patent Application Publication
(10) Pub. No.: US 2016/0362291 A1
(43) Pub. Date: Dec. 15, 2016

(54) MICROMECHANICAL COMPONENT HAVING A SPLIT, GALVANICALLY ISOLATED ACTIVE STRUCTURE, AND METHOD FOR OPERATING SUCH A COMPONENT

(71) Applicant: NORTHROP GRUMMAN LITEF GMBH, Freiburg (DE)

(72) Inventor: GUENTER SPAHLINGER, STUTTGART (DE)

(21) Appl. No.: 15/121,268

(22) PCT Filed: Feb. 11, 2015
(86) PCT No.: PCT/EP2015/000303

§ 371 Date: Aug. 24, 2016

(30) Foreign Application Priority Data
Feb. 25, 2014 (DE) 10 2014 002 823.2

(51) Int. Cl. B81B 3/00; G01C 19/5719

(52) U.S. Cl. CPC B81B 3/0045; G01C 19/5719; B81B 2203/0127; B81B 2203/04

(57) ABSTRACT

A micromechanical component comprises a substrate and an active structure which can be deflected in at least one direction relative to the substrate and which has at least a first region and a second region, wherein the first region and the second region are electrically conductive and are rigidly physically connected to one another along a first axis and are electrically insulated from one another by an insulating region. In a method for operating the component, different potentials are applied to the first region and the second region, wherein charges or changes in capacitance brought about by the movement of the active structure can be detected.

The invention relates to a component, in particular, a micromechanical, micro-electromechanical (MEMS) or rather micro-opto-electro-mechanical (MOEMS) component, which has a split, galvanically isolated active structure.

Micro-electromechanical components (MEMS) or rather micro-opto-electro-mechanical components (MOEMS) often comprise active structures. In this connection, in particular, mobile structures or structures, which equally include mobile and optical components (e.g. mobile mirrors), are to be understood by “active structure”. The term “active area” designates the area or rather volume of the component, in which the active structure lies or rather moves.

In micromechanical sensors, such as accelerometers and gyros, which are based on the function of a mechanical oscillator, i.e. on the movement of an active structure, both the drive of the oscillator and the detection of the deflection of the oscillator can be realized via movable electrodes on the active structure and fixed electrodes of the component. Essentially, there are two possibilities for this:

In a direct current method (DC method), the movable structure is connected to ground. Separate electrodes are used for the drive and detection functions, wherein the drive function must take into account the quadratic dependency of the drive force of the voltages applied. The detection function is based either on a measurement of charge transfers on electrodes biased with direct voltage or on a measurement of the capacitances of the detection electrodes. In the first case, no detection can be made due to charge drifts at zero frequency, which, for example, is given for a constant acceleration in accelerometers, in the second case, disruptive capacitances are measured, which reduces the accuracy to be achieved.

In a carrier frequency method, the movable structure is at the inlet of a charge amplifier and, thus, is connected to virtual ground. The charge amplifier provides the detection signal. The same electrodes are used for drive and detection, wherein drive and detection are realized separately, for example, through time multiplex in two phases. A direct voltage is applied in the drive phase, while a voltage with a carrier frequency is applied to the electrodes in the detection phase. In the simplest case, the carrier frequency can include a defined voltage jump and causes a deflection-dependent charge transfer on the movable electrode, which is then detected by the charge amplifier. In doing so, disruptive interactions between drive and detection can emerge. In sensors with a plurality of levels of freedom, for example, gyros or sensors with double oscillators, it can be necessary to use a complicated time multiplex method, in order to enable a separation of individual detection signals.

It is, therefore, an object of the invention to provide a micromechanical component that eliminates the aforementioned disadvantages of possible drive and detection methods as well as a method for operating such a component. In addition, it is an object of the invention to provide a component and a method, respectively, wherein a self-mixing function can be realized for drive and detection at the operating frequency of the component.

The object is solved by the subject matter of the independent claims. Preferred embodiments can be found in the sub-claims.

Embodiments of the component according to the invention and of the method according to the invention are explained in more detail in the following text based on the figures, with similar elements being designated with identical reference numerals. In addition, elements of the embodiments shown can also be arbitrarily combined with one another, as long as nothing to the contrary is mentioned.

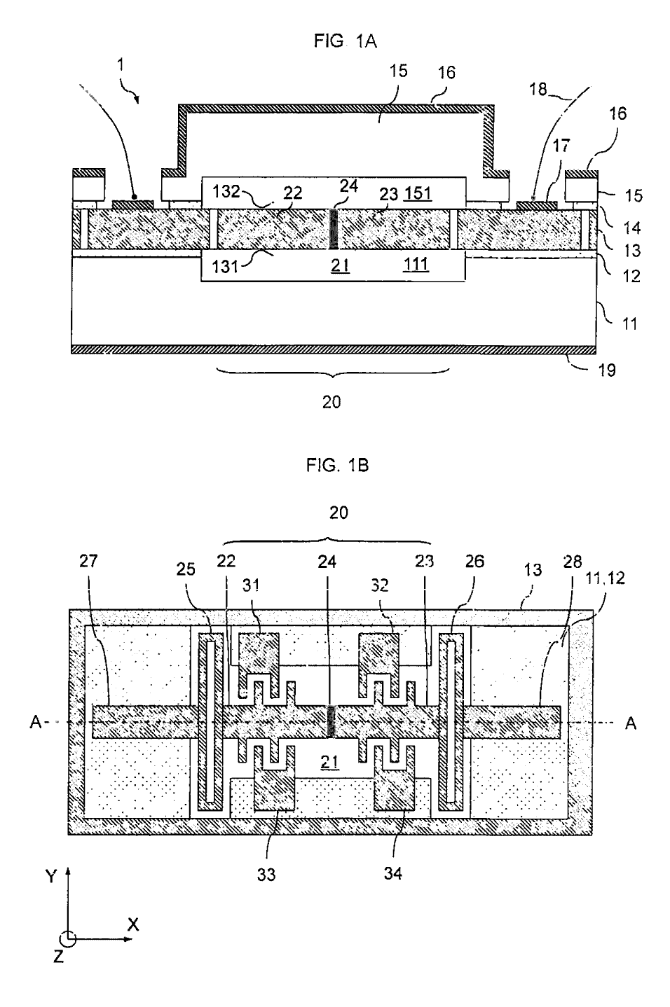

FIG. 1A shows a component according to an embodiment in cross section.

FIG. 1B shows a top view of the structure layer of the component from FIG. 1A.

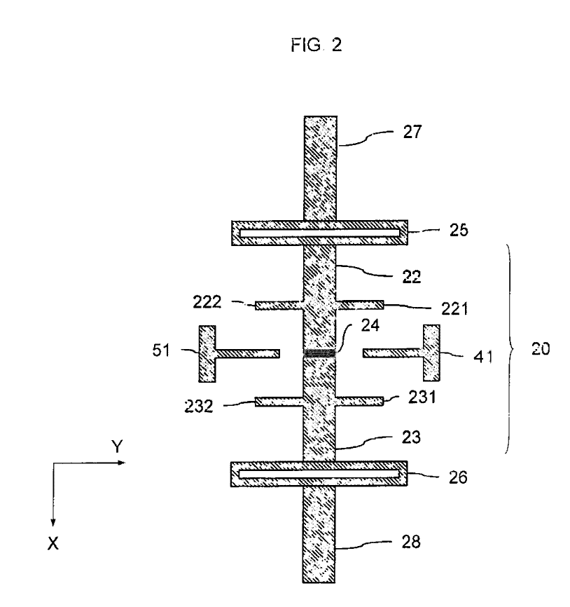

FIG. 2 shows an active structure and associated fixed electrodes of a first embodiment of the component in a top view.

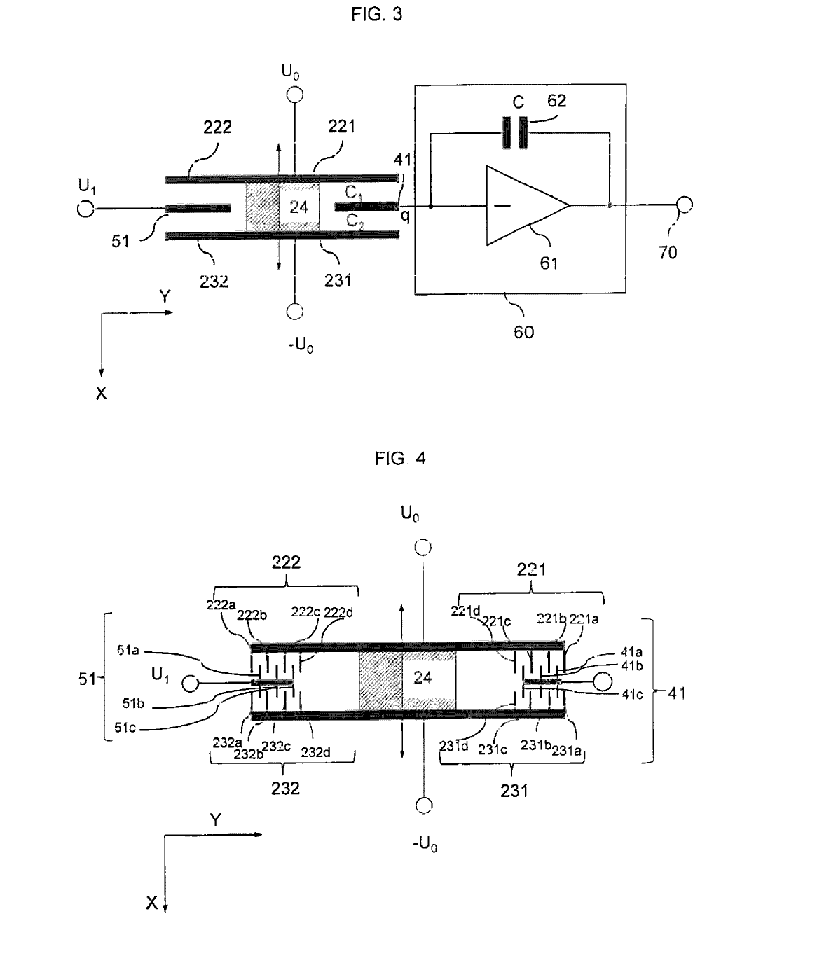

FIG. 3 schematically shows the electrode arrangement and the electric occupancy of the electrodes of the first embodiment of the component according to the invention.

FIG. 4 shows an exemplary embodiment of the electrodes of the first embodiment as immersing comb electrodes.

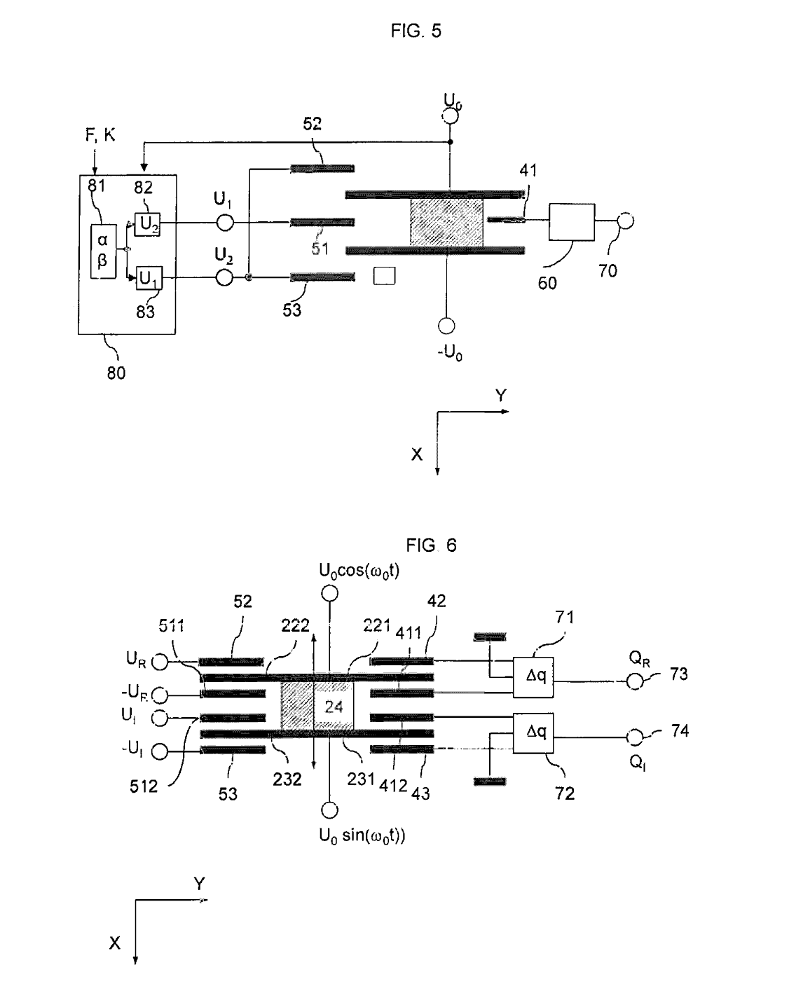

FIG. 5 schematically shows the electrode arrangement and the electric occupancy of the electrodes of a second embodiment of the component according to the invention.

FIG. 6 schematically shows the electrode arrangement and the electric occupancy of the electrodes of a third embodiment of the component according to the invention.

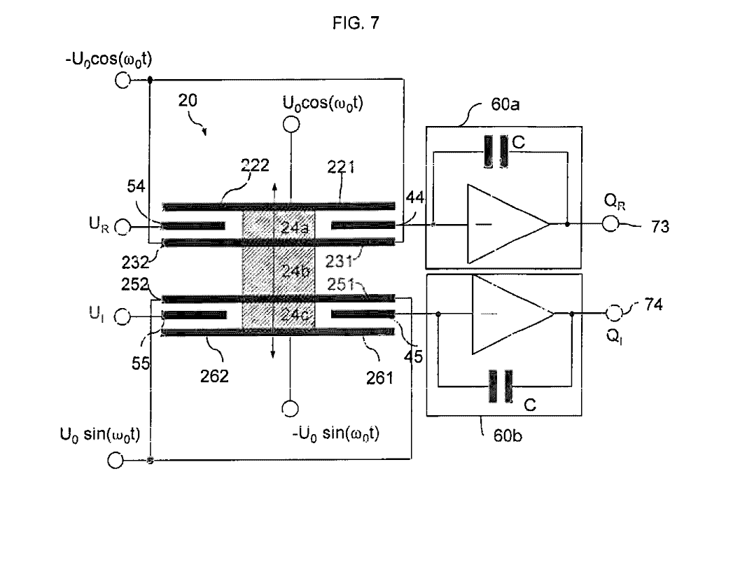

FIG. 7 schematically shows the electrode arrangement and the electric occupancy of the electrodes of a fourth embodiment of the component according to the invention.

FIG. 1 shows a cross section through a component 1 according to the invention according to an embodiment. The component 1 comprises a first substrate 11, a first insulation layer 12, a structure layer 13, a second insulation layer 14, and a second substrate 15. In addition, the component 1 can have a first cover layer 16, a contact surface 17 applied to the structure layer 13, a contact 18 connected to the contact surface 17, and a second cover layer 19.

The term “substrate” describes structures, which consist of one material only, for example, a silicon wafer or a glass plate, which, however, can also include a composite of a plurality of layers and materials. Accordingly, the first substrate 11 and/or the second substrate 15 can be fully electrically conductive, be electrically conductive in regions only, or consist of one electrically insulating material or of electrically insulating materials. In case that the first substrate 11 consists of an electrically insulating material, the first insulation layer 12 may also not exist. Similarly, the second insulation layer 14 can be saved, if the second substrate 15 consists of an electrically non-conductive material.

Also the term “structure layer” describes structures consisting of one material only, e.g. a silicon layer, which, however, can also include a composite made of a plurality of layers and materials, as long as at least one region of the structure layer 13 is electrically conductive. The electrically conductive regions of the structure layer 13 enable the application or readout of electric potentials on predetermined regions of the structure layer 13. Preferably, the structure layer 13 is fully electrically conductive.

The first cover layer 16, which is arranged on the surface of the second substrate 15 facing away from the structure layer 13, and the second cover layer 19, which is arranged on the surface of the first substrate 11 facing away from the structure layer 13, can consist of the same material, for example, a metal, or of different materials. They can serve to shield an active area of the component 1 from external electrical fields or other environmental impacts, such as humidity. In addition, they can serve to provide a defined electric potential on the first substrate 11 and on the second substrate 15, respectively. However, the first cover layer 16 and the second cover layer 19 are optional.

The first contact surface 17 consists of a conductive material, and serves the provision or readout (detection) of an electric potential on a certain region of the structure layer 13. The contact surface 17 can be contacted by means of a wire 18, as illustrated in FIG. 1A, however, other methods for producing an electric contact are also possible.

In the structure layer 13 an active structure 20 is formed, which can move at least in one direction in an active area 21. The active area 21 is, for example, realized by a first recess 111 formed in a surface of the first substrate 11 facing the structure layer, and a second recess 151 formed in a surface of the second substrate 15 facing the structure layer 13. The active structure 20 comprises at least a first region 22 and a second region 23, which are each electrically conductive, and are rigidly physically connected to one another along a first axis. The first region 22 and the second region 23 are electrically insulated from one another by an insulating region 24. The insulating region 24 extends across the whole depth of the structure layer 13, i.e. it extends from a first surface 131 of the structure layer 13 continuously to a second surface 132 of the structure layer 13. The first surface 131 faces the first substrate 11, while the second surface 132 faces the second substrate 15. The insulating region 24 can, for example, be realized by an insulating material, and can—both in the top view and in cross section—be arranged arbitrarily and have arbitrary forms. This means that the insulating region 24 can, in the top view, run straight or curved, for example, and can, in cross section, run straight or curved perpendicular to the first surface 131 and to the second surface 132 or at a defined angle to those surfaces. In addition, also the width of the insulating region 24 can vary in cross section, as long as full electric insulation of the first region 22 from the second region 23 of the structure layer 13 is ensured.

A top view of the structure layer of the component 1 from FIG. 1A is shown in FIG. 1B, wherein the sectional plane illustrated in FIG. 1A is characterized by the line A-A. As seen in FIG. 1B, the sectional plane A-A extends along a first axis of the component 1, which corresponds to the X axis. The structure layer 13 as well as regions of the first substrate 11 and of the first insulation layer 12 lying thereunder are illustrated in FIG. 1B. The active structure 20 is connected to the contact regions 27 and 28 of the structure layer 13 by means of springs 25 and 26, wherein the contact regions 27 and 28 are firmly connected to the first substrate 11 and, at least in regions, also firmly to the second substrate 15. The first region 22 of the active structure 20 is connected to the first contact region 27 of the structure layer 13 via the first spring 25, while the second region 23 of the active structure 20 is connected to the second contact region 28 of the structure layer 13 via the second spring 26. The first spring 25 and the second spring 26 allow movement of the active structure 20 at least along the first axis, i.e. in X direction, whereas, however, also movement of the active structure 20 along a second axis and/or along a third axis in a three-dimensional space, for example, in Y direction or in Z direction, is possible. The individual axes can each be perpendicular to one another or also have other angles to one another. In addition, the component 1 has further electrodes 31, 32, 33 and 34, which are rigidly connected to the first substrate 11 and/or to the second substrate 15 and serve as excitation, readout or resetting electrodes. They are arranged so that they project into the active area 21 of the component 1 and form capacitances with certain regions of the active structure 20, which are explained in more detail in the following text.

FIG. 2 shows an active structure and corresponding fixed electrodes of a first embodiment of the component in a top view, wherein, for a better understanding, also the first spring 25 and the second spring 26 as well as the first contact region 27 and the second contact region 28, as illustrated in FIG. 1B, are shown in addition to the active structure 20. However, the illustration of the active structure 20 and the regions of the structure layer 13 connected thereto are turned by 90° regarding the illustration in FIG. 1B. According to the first embodiment of the component according to the invention, the active structure 20 comprises the first region 22 and the second region 23, which are electrically insulated from one another by the insulating region 24. In addition, the active structure 20 comprises a first electrode 221, a second electrode 222, a third electrode 231, and a fourth electrode 232. The first electrode 221 is arranged in the first region 22, and extends outwards from it in a first direction along the second axis, i.e. the Y axis. The second electrode 222 is also arranged in the first region 22, however, extends outwards from it in a second direction along the second axis. The second direction runs opposite the first direction. The second axis, i.e. the Y axis, is perpendicular to the first axis, i.e. the X axis. The third electrode 231 and the fourth electrode 232 are arranged in the second region 23, wherein the third electrode extends outwards from the second region 23 in the first direction along the second axis, and the fourth electrode extends outwards from the second region 23 in the second direction along the second axis.

According to the first embodiment, the component 1 further comprises a fifth electrode 41, which is firmly connected to the first substrate 11 and/or to the second substrate 15 and extends outwards from it in the second direction along the second axis into the active area 21, wherein the fifth electrode 41 is arranged between the first electrode 221 and the third electrode 231. Furthermore, the component 1 can comprise a sixth electrode 51, which is firmly connected to the first substrate 11 and/or to the second substrate 15 and extends outwards from it in the first direction along the second axis into the active area 21 and is arranged between the second electrode 222 and the fourth electrode 232. Thus, the fifth electrode 41 and the sixth electrode 51 correspond to some extent to the electrode 32 or rather the electrode 33 illustrated in FIG. 1B, wherein the electrodes are differently designed and arranged compared to the embodiment illustrated in FIG. 1B.

FIG. 3 schematically shows the structure illustrated in FIG. 2 as an electrode arrangement as well as the electric occupancy of the electrodes in the first embodiment of the component according to the invention and of the method according to the invention to operate such a component. Thus, the active structure 20 as well as the fifth electrode 41 and the sixth electrode 51 are seen in FIG. 3, wherein the active structure 20 is only illustrated by the first electrode 221, the second electrode 222, the third electrode 231, and the fourth electrode 232 as well as the insulating region 24. The active structure is movably supported in a mechanical spring-loaded manner, as illustrated in FIG. 2, so that the active structure and thus the first to fourth electrodes 221 to 232 can move along the first axis, i.e. the X axis, which is symbolized by the arrow. Via the electrically conductive springs 25 and 26 and the associated contact regions 27 and 28 illustrated in FIG. 2, defined potentials can be applied to the electrodes 221 to 232.

In a first embodiment of the method for operating a component 1, a first voltage U₀, which is a direct voltage, is applied to the first electrode 221 and to the second electrode 222, i.e. to the first region 22. The negative first voltage, i.e. −U₀, is applied to the third electrode 231 and to the fourth electrode 232, i.e. to the second region 23. Thus, the first electrode 221 and the fifth electrode 41 form a first partial capacitance C₁, while the third electrode 231 and the fifth electrode 41 form a second partial capacitance C₂. The partial capacitances C₁ and C₂ induce a charge onto the fifth electrode 41, whereby:

Q=C₁·U₀−C₂·U₀=(C₁−C₂)·U₀ (1).

The fifth electrode 41 is connected to a charge amplifier 60, which comprises an operational amplifier 61 and a feedback capacitance 62. The charge amplifier 60 converts the charge Q induced onto the fifth electrode 41 into a voltage, which can be tapped at the first outlet 70. Thus, the fifth electrode 41 serves as a readout electrode, with the charge Q read out being proportional to the difference C₁−C₂, which is a measure for the deflection of the active structure 20, so that this deflection can be measured.

A second voltage U₁ can be applied via the sixth electrode 51, wherein that voltage U₁ is a drive or rather resetting voltage. The second voltage U₁ can be a direct voltage, for example, in accelerometers, or an alternating voltage, for example, in gyros. With the aid of the second voltage U₁, a resetting force F can be exercised on the active structure 20, wherein the resetting force F is proportional to the first voltage U₀ and to the second voltage U₁. The resetting force F is calculated as follows:

F=(U₁−U₀)²−(U₁+U₀)²=4·U₁·U₀ (2).

Since the first voltage U₀ occurs both in the readout process according to formula (1) and during the resetting process according to formula (2), modulation can be conducted on the drive side and demodulation on the readout side with the aid of the first voltage U₀.

If in the previously described components immersing combs are used for the first to sixth electrodes 221, 222, 231, 232, 41, and 51, so that the capacitances are a linear function of the deflection in X direction, no additional deflection-dependent forces emerge. Such an embodiment of the electrodes is illustrated in FIG. 4 by way of example. The individual electrodes are each formed as a comb structure, with each electrode comprising one or more partial structures that extend along the X direction. For example, the first electrode 221 comprises the partial structures 221a, 221b, 221c, and 221d, while the fifth electrode 41 comprises the partial structures 41a, 41b, 41c, and 41d. The partial structures of the first electrode 221 immerse into the partial structures of the fifth electrode 41, so that the partial structures overlap along the X axis. If the active structure of the component moves along the X axis, the partial structures of the first electrode 221 also move along the X axis, so that the length of the overlapping of the partial structures of the first electrode 221 changes with the partial structures of the fifth electrode 41. The same applies to the third electrode 231 regarding the fifth electrode 41 as well as to the second electrode 222 and the fourth electrode 232 regarding the sixth electrode 51. Although four partial structures are each illustrated for all electrodes, it is also possible that the electrodes comprise other numbers of partial structures and/or that the number of partial structures are different for different electrodes.

However, if one has capacitors with parallel, approximating electrodes, as illustrated in FIG. 3, terms of the second order occur in the deflection capacitance function, whereby forces dependent on the deflection occur in the form of negative spring constants. This negative electrostatic spring acts in addition to the mechanical first and second springs 25 and 26 illustrated in FIG. 2. This effect is essentially proportional to the sums of the weighted squares of the voltages between the electrodes of the capacitors concerned. The weightings depend on the geometry of each individual capacitor. If the models are equal, the spring constant induced on the drive side in the aforementioned example is proportional to

K=(U₁−U₀)²+(U₁+U₀)²=2U₁²+2U₀² (3).

This effect can be used for the tuning of the resonance frequency of the active structure 20. However, this effect can also be undesired, since the negative spring constant K depends on the second voltage U₁ at any time, and, therefore, can only be set jointly with the resetting force and not separate from it.

FIG. 5 schematically shows an electrode arrangement and the electric occupancy of the electrodes according to a second embodiment of the component according to the invention and of the method according to the invention for operating such a component, by which that negative effect can be eliminated.

The second embodiment illustrated in FIG. 4 differs from the first embodiment of the component according to the invention illustrated in FIG. 3 in that the component further comprises a seventh electrode 52 and an eighth electrode 53. The seventh electrode 52 and the eighth electrode 53 are each firmly connected to the first substrate 11 and/or to the second substrate 15, and extend outwards from it into the active area 21 in the first direction along the second axis. This means that the seventh electrode 52 and the eighth electrode 53 extend in the same direction as the sixth electrode 51. The seventh electrode is arranged so that the second electrode 222 is arranged between the sixth electrode 51 and the seventh electrode 52, whereas the eighth electrode 53 is arranged so that the fourth electrode 232 is arranged between the sixth electrode 51 and the eight electrode 53.

According to an embodiment for operating the component in the second embodiment, a third voltage U₂ is applied to the seventh and eighth electrodes 52, 53, which serves for compensation of the spring constants of the first spring 25 and of the second spring 26, by which the active structure 20 is movably connected to the first substrate 11 and/or to the second substrate 15. The resetting force F and the spring constant K induced on the drive side, which are to be set on the component and thus are preset, can be calculated here as follows:

F=4·(U₁−U₂)·U₀ (4).

K=4·U₀²+2U₁²+2U₂² (5).

Thus, parameters α and β can be introduced, for which applies:

α=U₁−U₂ (6).

β=U₁+U₂ (7).

If one inserts formulas (6) and (7), respectively, into the formulas (4) and (5), respectively, then one obtains:

F=4·α·U₀ (8).

K=4·U₀²+α²+β² (9).

Thus, signal processing, which serves to detect movement of the active structure 20 or control the applied drive and resetting force, respectively, and of the spring constants, i.e. to control the second voltage U₁ and the third voltage U₂, is to solve the following equations:

$$\begin{matrix}α = \frac{F}{4 \cdot {U}_{0}} , & ( 10 ) \\ β = \sqrt{K - 4 \cdot {U}_{0}^{2} - {α}^{2}} , & ( 11 ) \\ {U}_{1} = \frac{α + β}{2} , & ( 12 ) \\ {U}_{2} = \frac{β - α}{2} . & ( 13 )\end{matrix}$$

This signal processing can be realized by a control unit 80, which is schematically illustrated in FIG. 5. The values to be set for the resetting force F and the spring constant K are provided to the control unit 80 by a controller or another control unit of a system, which includes the component. In addition, the first voltage U₀ is made available to the control unit 80 for the calculations to be made. The control unit 80 comprises a first unit 81 to calculate the parameters α and β according to the formulas (10) and (11), a second unit 82 to calculate the second voltage U₁ according to the formula (12), and a third unit 83 to calculate the third voltage U₂ according to the formula (13). The second voltage U₁, which is applied to the sixth electrode, is set in line with a value to be calculated by the second unit 82 respectively a signal corresponding thereto. The third voltage U₂, which is applied to the seventh electrode 58 and to the eighth electrode 53, is set in line with a value to be calculated by the third unit 83 respectively a signal corresponding thereto. Thus, a control circuit for controlling the second voltage U₁ and the third voltage U₂ can be realized.

The previously illustrated and described embodiments of the method for operating a component are characterized in that a direct voltage has been applied to the electrodes of the active structure 20. As already described in the prior art, however, an alternating voltage can also be applied to the active structure, whereby self-mixing drive and readout functions can be realized. “Self-mixing” means that in gyros, which operate at an operating frequency ω₀ (resonance frequency), a resetting force can be obtained at the operating frequency ω₀ by applying direct voltages to the drive electrodes, whereas a deflection at the operating frequency ω₀ supplies direct voltage values to the readout electrodes, respectively to the charge amplifier, i.e. for detection.

With reference to FIG. 6, which schematically shows an electrode arrangement and the electric occupancy of the electrodes according in a third embodiment of the component according to the invention and of the method according to the invention for operating such a component, such a method is to be described. A first voltage U₀·cos(ω₀·t) is applied to the first electrode 221 and to the second electrode 222, i.e. to the first region 22 of the active structure 20, whereas a time-delayed second voltage U₀·sin(ω₀·t) is applied to the second region 23 of the active structure 20, i.e. to the third electrode 231 and to the fourth electrode 232.

As illustrated in FIG. 6, the component 1 has a first fifth electrode 411 and a second fifth electrode 412, which are both arranged between the first electrode 221 and the third electrode 231 and otherwise extend as the fifth electrode 41 described with regard to the FIGS. 3 and 4. This means: The first fifth electrode 411 and the second fifth electrode 412 are firmly connected to the first substrate 11 and/or to the second substrate 15, and extend outwards from it into the active area 21 in a second direction along the second axis, i.e. the Y axis.

In addition, the component 1 has a ninth electrode 42 and a tenth electrode 43, which both are each connected to the first substrate 11 and/or to the second substrate 15, and extend outwards from it in the second direction along the second axis, i.e. the Y axis, into the active area 21. The ninth electrode 42 is arranged so that the first electrode 221 is arranged between the first fifth electrode 411 and the ninth electrode 42, whereas the tenth electrode 43 is arranged so that the third electrode 231 is arranged between the second fifth electrode 412 and the tenth electrode 43.

The component 1 further comprises a first signal-processing unit and a second signal-processing unit 72. The first fifth electrode 411 and the ninth electrode 42 are connected to the first signal-processing unit 71, which determines a charge difference between these two electrodes, and provides a charge Q_{R} or a voltage corresponding thereto at a first outlet 73. The second fifth electrode 412 and the tenth electrode 43 are connected to the second signal-processing unit 72, which also determines a charge difference and provides a charge Q_{I} or rather a voltage corresponding thereto at a second outlet 74.

The component 1 further has a first sixth electrode 511 and a second sixth electrode 512, which are both arranged between the second electrode 222 and the fourth electrode 232 and otherwise extend as the sixth electrode 51 described with regard to the FIGS. 3 and 4. This means that the first sixth electrode 511 and the second sixth electrode 512 are firmly connected to the first substrate 11 and/or to the second substrate 15, and extend outwards from it in the first direction along the second axis, i.e. the Y axis, into the active area 21. In addition, the component 1 has a seventh electrode 52 and an eighth electrode 53, as they have already been described with reference to FIG. 4. Thus, the second electrode 222 is arranged between the first sixth electrode 511 and the seventh electrode 52, whereas the fourth electrode 232 is arranged between the second sixth electrode 512 and the eighth electrode 53.

According to the third embodiment of the method for operating the component, a third voltage U_{R} is applied to the seventh electrode 52, while the negative third voltage −U_{R} is applied to the first sixth electrode 511.

A fourth voltage U_{I} is applied to the second sixth electrode 512, while the negative fourth voltage −U_{I} is applied to the eighth electrode 53.

The third voltage U_{R} and the fourth voltage U_{I} are direct voltages, the polarity of which, however, can be periodically reversed at a low frequency.

Thus, the force acting on the active structure 20 can be calculated as follows:

F=U_{R}·U₀·cos(ω₀·t)+U_{I}·U₀·sin(ω₀·t) (14).

The readout charges Q_{R} and Q_{I} are as follows:

Q_{R}=ΔC·U₀·cos(ω₀·t) (15).

Q_{I}=ΔC·U₀·cos(ω₀·t) (16).

The capacitance difference ΔC resulting from the difference of the partial capacitances C₂−C₁ is a measure for the deflection of the active structure 20.

Thus, both the normal and the quadrature components can be correctly processed both on the drive side and on the readout side.

To compensate for the drift of a charge amplifier at ω=0, the polarity of the first voltage U₀·cos(ω₀·t) and of the second voltage U₀·sin(ω₀·t) applied to the active structure 20 as well as of the third voltage U_{R} and of the fourth voltage U_{I} applied to the drive electrodes can be periodically reversed at a lower frequency. In this case, the readout charges Q_{R} and Q_{I} are demodulated in the same cycle.

In FIG. 7 the electrode arrangements and electric occupancies of the electrodes of another self-mixing variant according a fourth embodiment of the component according to the invention and of the method according to the invention for operating the component are schematically illustrated. The component not only has two electrically conductive insulating regions of the active structure, rigidly physically connected to one another along the first axis (X axis), but electrically insulated from one another, as this has been the case in the previously illustrated embodiments, but four such regions.

As illustrated in FIG. 7, the active structure 20 thus comprises a first region 22 having a first electrode 221 and a second electrode 222, a second region 23 having a third electrode 231 and a fourth electrode 232, a third region 250 having a fifth electrode 251 and a sixth electrode 252 as well as a fourth region 260 having a seventh electrode 261 and an eighth electrode 262. The individual regions 22, 23, 250, and 260 are each electrically conductive and are rigidly physically connected to one another along the first axis. However, they are electrically insulated from one another by insulating regions 24a, 24b, and 24c. In particular, the first region 22 and the second region 23 are insulated from one another by a first insulating region 24a, the second region 23 and the third region 250 are insulated from one another by a second insulating region 24b, and the third region 250 and the fourth region 260 are insulated from one another by a third insulating region 24c. Regarding the insulating regions 24a to 24c, the statements already made with reference to FIG. 1A apply.

The first electrode 221 extends outwards from the first region 22 in the first direction along the second axis, i.e. the Y axis, while, however, the second electrode 222 extends outwards from it in the second direction along the second axis, wherein the second direction runs opposite the first direction. The third electrode 231 and the fourth electrode 232 are arranged in the second region 23, wherein the third electrode extends outwards from the second region 23 in the first direction along the second axis, and the fourth electrode extends outwards from the second region 23 in the second direction along the second axis. The fifth electrode 251 and the sixth electrode 252 are arranged in the third region 250, wherein the fifth electrode extends outwards from the third region 250 in the first direction along the second axis, and the sixth electrode extends outwards from the third region 250 in the second direction along the second axis. The seventh electrode 261 and the eighth electrode 262 are arranged in the fourth region 260, wherein the seventh electrode extends outwards from the fourth region 260 in the first direction along the second axis, and the eighth electrode extends outwards from the fourth region 260 in the second direction along the second axis.

According to the fourth embodiment, the component further comprises a ninth electrode 44 and a tenth electrode 45, which are firmly connected to the first substrate 11 and/or to the second substrate 15 and extend outwards from it in the second direction along the second axis into the active area 21, wherein the ninth electrode 44 is arranged between the first electrode 221 and the third electrode 231, and the tenth electrode 45 is arranged between the fifth electrode 251 and the seventh electrode 261. Furthermore, the component comprises an eleventh electrode 54 and a twelfth electrode 55, which are firmly connected to the first substrate 11 and/or to the second substrate 15 and extend outwards from it in the first direction along the second axis into the active area 21, wherein the eleventh electrode 54 is arranged between the second electrode 222 and the fourth electrode 232, and the twelfth electrode is arranged between the sixth electrode 252 and the eighth electrode 262.

The active structure and, thus, the first to eighth electrodes 221 to 262 can move along the first axis, i.e. the X axis, which is symbolized by the arrow.

In the fourth embodiment of the method for operating a component, a first voltage U₀·cos(ω₀·t) is applied to the first electrode 221 and to the second electrode 222, i.e. to the first region 22. The negative first voltage, i.e. −U₀·cos(ω₀·t), is applied to the third electrode 231 and to the fourth electrode 232, i.e. to the second region 23. Thus, the first electrode 221 and the ninth electrode 44 form a first partial capacitance C₁, while the third electrode 231 and the ninth electrode 44 form a second partial capacitance C₂. The partial capacitances C₁ and C₂ induce a charge Q_{R} onto the ninth electrode 44, which can be amplified with the aid of a simple charge amplifier 60a and read out as voltage at a first outlet 73.

A time-delayed second voltage U₀·sin(ω₀·t) is applied to the fifth electrode 251 and to the sixth electrode 252, i.e. to the third region 250. The negative second voltage, i.e. −U₀·sin(ω₀·t), is applied to the seventh electrode 261 and to the eighth electrode 262, i.e. to the fourth region 260. Thus, the fifth electrode 251 and the tenth electrode 45 form a third partial capacitance C₃, while the seventh electrode 271 and the tenth electrode 45 form a fourth partial capacitance C₄. The partial capacitances C₃ and C₄ induce a charge Q_{I} onto the tenth electrode 45, which can be amplified with the aid of another simple charge amplifier 60b and read out as voltage at a second outlet 74.

A third voltage U_{R} can be applied via the eleventh electrode 54, while a fourth voltage U_{I} is applied to the twelfth electrode 55. The third voltage U_{R} and the fourth voltage U_{I} are direct voltages, the polarity of which, however, can be periodically reversed at a low frequency.

Thus, the resetting force F acting on the active structure 20 can also be calculated according to formula (14). However, contrary to the third embodiment illustrated in FIG. 6, only simple charge amplifiers 60a and 60b are necessary to read out charges Q_{R} and Q_{I}.

The illustrated embodiments of the component according to the invention and of the method according to the invention for operating such a component enable complete separation of the functions for drive and detection. Both non-mixing configurations with each an electrode for the drive and an electrode for the detection and self-mixing configurations with a plurality of electrodes for the drive and the detection can be realized. In addition, the negative spring constant of the springs 25 and 26, by which the active structure 20 is connected to the first substrate 11 and/or the second substrate 15, can be used for tuning the resonance frequency of the active structure 20. However, it is also possible to eliminate the effect of the negative spring constant.

When applying a direct voltage to the electrodes of the active structure 20, a linear tension force function can be realized for the drive, wherein harmful capacitances are ineffective in the detection of the deflection of the active structure 20, whereby a higher accuracy of the detection can be achieved. If multiple oscillators, i.e. active structures consisting of a plurality of structures movably supported relative to one another, are used, then the drive and detection functions can be fully separated from one another, so that no time multiplex is necessary. In addition, it is possible to use low bandwidths of the drive voltage for the drive and the charge amplifiers for the detection in gyros operating at an operating frequency ω₀.

1. A micromechanical component comprising:
a substrate, and
an active structure, which can be deflected in at least one direction relative to the substrate, and which has at least a first region and a second region, wherein the first region and the second region are electrically conductive and are rigidly physically connected to one another along a first axis (x) and are electrically insulated from one another by an insulating region.

2. The component according to claim 1, further comprising:
a first electrode, which extends outwards from the first region in a first direction along a second axis (y), and a second electrode, which extends outwards from the first region in a second direction along the second axis (y), wherein the second axis (y) is perpendicular to the first axis (x), and wherein the second direction is opposite to the first direction, and
a third electrode, which extends outwards from the second region in the first direction along the second axis (y), and a fourth electrode, which extends outwards from the second region in the second direction along the second axis (y).

3. The component according to claim 2, further comprising:
a fifth electrode, which is firmly connected to the substrate and extends outwards from the substrate in the second direction along the second axis (y), and is arranged between the first electrode and the third electrode.

4. The component according to claim 3,
characterized in that
the fifth electrode is connected to a charge amplifier.

5. The component according to claim 2, further comprising:
a sixth electrode, which is firmly connected to the substrate, and extends outwards from the substrate in the first direction along the second axis (y) and is arranged between the second electrode and the fourth electrode.

6. The component according to claim 5, further comprising:
a seventh electrode, and
an eighth electrode,
wherein the seventh electrode and the eighth electrode are firmly connected to the substrate, and extend outwards from the substrate in the first direction along the second axis (y), and
wherein the seventh electrode and the eighth electrode are arranged so that the second electrode is arranged between the sixth electrode and the seventh electrode, and the fourth electrode is arranged between the sixth electrode and the eighth electrode.

7. The component according to claim 6,
characterized in that
the component comprises a control unit, which is connected to the sixth electrode, to the seventh electrode and to the eighth electrode, and which is suited to calculate, based on a first voltage (U₀) applied to the first region (22), a preset resetting force (F) and a preset spring constant (K), signals to control a second voltage (U₁) applied to the sixth electrode, and to control a third voltage (U₂) applied to the seventh electrode and to the eighth electrode.

8. The component according to claim 6,
characterized in that
a first sixth electrode and a second sixth electrode are arranged between the second electrode and the fourth electrode,
wherein the second electrode is arranged between the first sixth electrode and the seventh electrode, and the fourth electrode is arranged between the second sixth electrode and the eighth electrode.

9. The component according to claim 3,
characterized in that
a first fifth electrode and a second fifth electrode are arranged between the first electrode and the third electrode,
the component further comprises a ninth electrode and a tenth electrode, wherein the ninth electrode and the tenth electrode are firmly connected to the substrate and extend outwards from the substrate in the second direction along the second axis (y) and are arranged so that the first electrode is arranged between the first fifth electrode and the ninth electrode, and the third electrode is arranged between the second fifth electrode and the tenth electrode.

10. The component according to claim 9,
characterized in that
the first fifth electrode and the ninth electrode are connected to a first signal-processing unit, and the second fifth electrode and
the tenth electrode are connected to a second signal-processing unit.

11. The component according to claim 1,
characterized in that
the active structure further has a third region and a fourth region, wherein the third region and the fourth region are electrically conductive and are rigidly physically connected to the first region and to the second region along the first axis (x), wherein the first region is electrically insulated from the second region by a first insulating region, and the third region is electrically insulated from the second region by a second insulating region and from the fourth region by a third insulating region.

12. The component according to claim 11,
characterized in that
a first electrode extends outwards from the first region in a first direction along a second axis (y), and a second electrode extends outwards from the first region in a second direction along the second axis (y), wherein the second axis (y) is perpendicular to the first axis (x), and wherein the second direction is opposite to the first direction,
a third electrode extends outwards from the second region in the first direction along the second axis (y), and a fourth electrode extends outwards from the second region in the second direction along the second axis (y),
a fifth electrode extends outwards from the third region in the first direction along the second axis (y), and a sixth electrode extends outwards from the third region in the second direction along the second axis (y), and
a seventh electrode extends outwards from the fourth region in the first direction along the second axis (y), and an eighth electrode extends outwards from the fourth region in the second direction along the second axis (y).

13. The component according to claim 12, further comprising:
a ninth electrode, which is firmly connected to the substrate and extends outwards from the substrate in the second direction along the second axis (y), and is arranged between the first electrode and the third electrode,
a tenth electrode, which is firmly connected to the substrate and extends outwards from the substrate in the second direction along the second axis (y), and is arranged between the fifth electrode and the seventh electrode,
an eleventh electrode, which is firmly connected to the substrate, and extends outwards from the substrate in the first direction along the second axis (y) and is arranged between the second electrode and the fourth electrode, and
a twelfth electrode, which is firmly connected to the substrate and extends outwards from the substrate in the first direction along the second axis (y), and is arranged between the sixth electrode and the eighth electrode.

14. The component according to claim 13,
characterized in that
the ninth electrode and the tenth electrode are each connected to an associated charge amplifier.

15. A method for operating a micromechanical component
comprising a substrate, and
an active structure, which can be deflected in at least one direction relative to the substrate, and which has at least a first region and a second region, wherein the first region and the second region are electrically conductive and are rigidly physically connected to one another along a first axis (x) and are electrically insulated from one another by an insulating region,
comprising:
the step of applying a first voltage (U₀) to the first region, wherein the first voltage (U₀) is a direct voltage, and
the step of applying the negative first voltage (−U₀) to the second region.

16. The method according to claim 15,
characterized in that
the component further comprises:
a first electrode, which extends outwards from the first region in a first direction along a second axis (y), and a second electrode, which extends outwards from the first region in a second direction along the second axis (y), wherein the second axis (y) is perpendicular to the first axis (x), and wherein the second direction is opposite to the first direction,
a third electrode, which extends outwards from the second region in the first direction along the second axis (y), and a fourth electrode, which extends outwards from the second region in the second direction along the second axis (y), and
a fifth electrode, which is firmly connected to the substrate and extends outwards from the substrate in the second direction along the second axis (y), and is arranged between the first electrode and the third electrode; and
the method comprises the determination of a charge (q), which is generated on the fifth electrode.

17. The method according to claim 16,
characterized in that
for the determination of the charge, a charge amplifier, which is connected to the fifth electrode, is used.

18. The method according to claim 16,
characterized in that
the component further comprises a sixth electrode, which is firmly connected to the substrate and extends outwards from the substrate in the first direction along the second axis (y), and is arranged between the second electrode and the fourth electrode; and
a second voltage (U₁), which exercises a force proportional to the first voltage (U₀) and to the second voltage (U₁) on the active structure, is applied to the sixth electrode.

19. The method according to claim 18,
characterized in that
the component further comprises a seventh electrode and an eighth electrode,
wherein the seventh electrode and the eighth electrode (53) are firmly connected to the substrate, and extend outwards from the substrate in the first direction along the second axis (y), and
wherein the seventh electrode and the eighth electrode are arranged so that the second electrode is arranged between the sixth electrode and the seventh electrode, and the fourth electrode is arranged between the sixth electrode and the eighth electrode; and
a third voltage (U₂) is applied to the seventh and eighth electrodes, which serves for compensation of the spring constants of springs, by which the active structure is movably connected to the substrate.

20. The method according to claim 19,
characterized in that
the second voltage (U₁) and the third voltage (U₂) are controlled by a control circuit, wherein the control circuit comprises a control unit, which calculates, based on the first voltage (U₀), a preset resetting force (F) and a preset spring constant (K), signals to control the second voltage (U₁) and the third voltage (U₂).

21. A method for operating a micromechanical component
comprising a substrate, and
an active structure, which can be deflected in at least one direction relative to the substrate, and which has at least a first region and a second region, wherein the first region and the second region are electrically conductive and are rigidly physically connected to one another along a first axis (x) and are electrically insulated from one another by an insulating region,
comprising:
the step of applying a first voltage (U₀·cos(ω₀t)) to the first region, wherein the first voltage (U₀) is an alternating voltage, and
the step of applying a second voltage (U₀·sin(ω₀t)), which is equal to the first voltage (U₀·cos(ω₀t)), but time-delayed, to the second region.

22. The method according to claim 21,
characterized in that
the component further comprises:
a first electrode, which extends outwards from the first region in a first direction along a second axis (y), and a second electrode, which extends outwards from the first region in a second direction along the second axis (y), wherein the second axis (y) is perpendicular to the first axis (x), and wherein the second direction is opposite to the first direction,
a third electrode, which extends outwards from the second region in the first direction along the second axis (y), and a fourth electrode, which extends outwards from the second region in the second direction along the second axis (y),
a first fifth electrode and a second fifth electrode, which are firmly connected to the substrate and extend outwards from the substrate in the second direction along the second axis (y), and are arranged between the first electrode and the third electrode,
a first sixth electrode and a second sixth electrode, which are firmly connected to the substrate and extend outwards from the substrate in the first direction along the second axis (y), and are arranged between the second electrode and the fourth electrode,
a seventh electrode and an eighth electrode, which are firmly connected to the substrate and extend outwards from the substrate in the first direction along the second axis (y) and are arranged so that the second electrode is arranged between the first sixth electrode and the seventh electrode, and the fourth electrode is arranged between the second sixth electrode and the eighth electrode, and
a ninth electrode and a tenth electrode, which are firmly connected to the substrate and extend outwards from the substrate in the second direction along the second axis (y), and are arranged so that the first electrode is arranged between the first fifth electrode and the ninth electrode, and the third electrode is arranged between the second fifth electrode and the tenth electrode;
a third voltage (U_{R}) is applied to the seventh electrode, wherein the third voltage (U_{R}) is a direct voltage;
the negative third voltage (−U_{R}) is applied to the first sixth electrode;
a fourth voltage (U_{I}) is applied to the second sixth electrode, wherein the fourth voltage (U_{I}) is a direct voltage; and
the negative fourth voltage (−U_{I}) is applied to the eighth electrode.

23. The method according to claim 22,
characterized in that
the first fifth electrode and the ninth electrode are connected to a first signal-processing unit, and
the second fifth electrode and the tenth electrode are connected to a second signal-processing unit,
wherein in the first signal-processing unit and in the second signal-processing unit a charge difference (ΔQ) is each determined, which is a measure for the deflection of the active structure.

24. A method for operating a micromechanical component
comprising a substrate, and
an active structure, which can be deflected in at least one direction relative to the substrate, and which has a first region, a second region, a third region and a fourth region, wherein the first region, the second region, the third region and the fourth region are electrically conductive and are rigidly physically connected to one another along a first axis (x) and are each electrically insulated from one another by an insulating region,
comprising:
the step of applying a first voltage (U₀·cos(ω₀t)) to the first region, wherein the first voltage (U₀) is an alternating voltage,
the step of applying the negative first voltage (−U₀·cos(ω₀t)) to the second region,
the step of applying a second voltage (U₀·sin(ω₀t)), which is equal to the first voltage (U₀·cos(ω₀t)), but time-delayed, to the third region, and
the step of applying the negative second voltage (−U₀·sin(ω₀t)) to the fourth region.

25. The method according to claim 24,
characterized in that
the component further comprises:
a first electrode, which extends outwards from the first region in a first direction along a second axis (y), and a second electrode, which extends outwards from the first region in a second direction along the second axis (y), wherein the second axis (y) is perpendicular to the first axis (x), and wherein the second direction is opposite to the first direction,
a third electrode, which extends outwards from the second region in the first direction along the second axis (y), and a fourth electrode, which extends outwards from the second region in the second direction along the second axis (y),
a fifth electrode extends outwards from the third region in the first direction along the second axis (y), and a sixth electrode extends outwards from the third region in the second direction along the second axis (y),
a seventh electrode extends outwards from the fourth region in the first direction along the second axis (y), and an eighth electrode extends outwards from the fourth region in the second direction along the second axis (y),
a ninth electrode, which is firmly connected to the substrate and extends outwards from the substrate in the second direction along the second axis (y), and is arranged between the first electrode and the third electrode,
a tenth electrode, which is firmly connected to the substrate and extends outwards from the substrate in the second direction along the second axis (y), and is arranged between the fifth electrode and the seventh electrode,
the method for determining a first charge (Q_{R}), which is generated on the ninth electrode, and a second charge (Q_{I}), which is generated on the tenth electrode.

26. The method according to claim 25,
characterized in that
the first charge (Q_{R}) is determined by a first charge amplifier, and
the second charge (Q_{I}) is determined by a second charge amplifier.

27. The method according to claim 25,
characterized in that
the component further comprises:
an eleventh electrode, which is firmly connected to the substrate and extends outwards from the substrate in the first direction along the second axis (y), and is arranged between the second electrode and the fourth electrode, and
a twelfth electrode, which is firmly connected to the substrate and extends outwards from the substrate in the first direction along the second axis (y), and is arranged between the sixth electrode and the eighth electrode;
a third voltage (U_{R}) is applied to the eleventh electrode, wherein the third voltage (U_{R}) is a direct voltage, and
a fourth voltage (U_{I}) is applied to the twelfth electrode, wherein the fourth voltage (U_{I}) is a direct voltage.
